(19) United States
(12) Patent Application Publication
(10) Pub. No.: US 2025/0202192 A1
(43) Pub. Date: Jun. 19, 2025

(54) LIGHT-EMITTING DEVICE

(71) Applicant: NICHIA CORPORATION, Anan-shi, Tokushima (JP)

(72) Inventor: Kazuma KOZURU, Anan-shi (JP)

(73) Assignee: NICHIA CORPORATION, Anan-shi, Tokushima (JP)

(21) Appl. No.: 18/844,230

(22) PCT Filed: Feb. 8, 2023
(86) PCT No.: PCT/JP2023/004114

§ 371 Date: Sep. 5, 2024

(30) Foreign Application Priority Data
Mar. 17, 2022 (JP) 2022-043122

(51) Int. Cl. H01S 5/042; H01S 5/42

(52) U.S. Cl. CPC H01S 5/04256; H01S 5/423

(57) ABSTRACT

A light-emitting device includes: a substrate having an upper surface; a light-transmissive member having a lower surface facing the upper surface of the substrate; a plurality of surface emitting laser elements disposed between the upper surface of the substrate and the lower surface of the light-transmissive member, the surface emitting laser elements being configured to perform top emission; and an intermediate conductive component disposed between the upper surface of the substrate and the lower surface of the light-transmissive member. The substrate includes a first conductive member and a second conductive member. The light-transmissive member includes a third conductive member electrically connected to the first conductive member by the intermediate conductive component. The plurality of surface emitting laser elements include a first laser element electrically connected to the third conductive member, and a second laser element electrically connected to the second conductive member.

### TECHNICAL FIELD

The present disclosure relates to a light-emitting device.

### BACKGROUND ART

Patent Document 1 discloses a light-emitting device including a vertical cavity surface emitting laser (hereinafter referred to as a “VCSEL”) element.

### CITATION LIST

### Patent Literature

Patent Document 1: JP 2009-146979 A

### SUMMARY OF INVENTION

### Technical Problem

There is a demand for reduction in size of a light-emitting device including the surface emitting laser element, such as the VCSEL element.

### Solution to Problem

A light-emitting device according to one embodiment of the present disclosure includes a substrate having an upper surface: a light-transmissive member having a lower surface facing the upper surface of the substrate: a plurality of surface emitting laser elements disposed between the upper surface of the substrate and the lower surface of the light-transmissive member, the surface emitting laser elements being configured to perform top emission; and an intermediate conductive component disposed between the upper surface of the substrate and the lower surface of the light-transmissive member. The substrate includes a first conductive member and a second conductive member. The light-transmissive member includes a third conductive member electrically connected to the first conductive member by the intermediate conductive component. The plurality of surface emitting laser elements include a first laser element electrically connected to the third conductive member, and a second laser element electrically connected to the second conductive member.

### Advantageous Effects of Invention

The light-emitting device including the surface emitting laser element can be reduced in size.

### BRIEF DESCRIPTION OF DRAWINGS

FIG. 1 is an exploded perspective view schematically illustrating a configuration of a light-emitting device according to an exemplary first embodiment of the present disclosure.

FIG. 2A is a top view schematically illustrating a substrate, three VCSEL elements, and an intermediate conductive component in the light-emitting device illustrated in FIG. 1.

FIG. 2B is a top view schematically illustrating a patterned conductive member in addition to the configuration illustrated in FIG. 2A.

FIG. 2C is a side view of the light-emitting device illustrated in FIG. 1 when seen from a −Y direction side.

FIG. 2D is a side view schematically illustrating a modified example of the light-emitting device according to the first embodiment.

FIG. 2E is a top view schematically illustrating a substrate, three VCSEL elements, an intermediate conductive component, and a patterned conductive member in a light-emitting device according to another modified example of the first embodiment.

FIG. 3 is a side view schematically illustrating a configuration of a light-emitting device according to an exemplary second embodiment of the present disclosure when seen from the −Y direction side.

FIG. 4 is a side view schematically illustrating a configuration of a light-emitting device according to an exemplary third embodiment of the present disclosure when seen from the −Y direction side.

FIG. 5A is a cross-sectional view parallel to a YZ plane, schematically illustrating a part of a configuration example of a first VCSEL element.

FIG. 5B is a top view of a part of the configuration example illustrated in FIG. 5A.

FIG. 6 is a cross-sectional view parallel to the YZ plane, schematically illustrating a part of a configuration example of a second VCSEL element.

### DESCRIPTION OF EMBODIMENTS

A light-emitting device according to an embodiment of the present disclosure will be described below with reference to the drawings. Parts designated the same reference characters appearing in the plurality of drawings indicate identical or equivalent parts.

The following description is intended as examples to embody the technical idea of the present invention, and the present invention is not limited to the following description. The descriptions of dimensions, materials, shapes, relative arrangements, and the like of components are not intended to limit the scope of the present invention thereto but intended to be illustrative. The size, positional relationship, and the like of the members illustrated in the drawings may be exaggerated in order to facilitate understanding and the like.

Further, in this specification or the scope of the claims, when there are a plurality of components corresponding to a certain component and each of the components is to be expressed separately, the components may be distinguished by adding the terms “first” and “second” in front of the component term. When distinguished objects or viewpoints differ between this specification and the scope of the claims, the same added terms in the specification and the scope of the claims sometimes does not refer to the same objects.

### First Embodiment

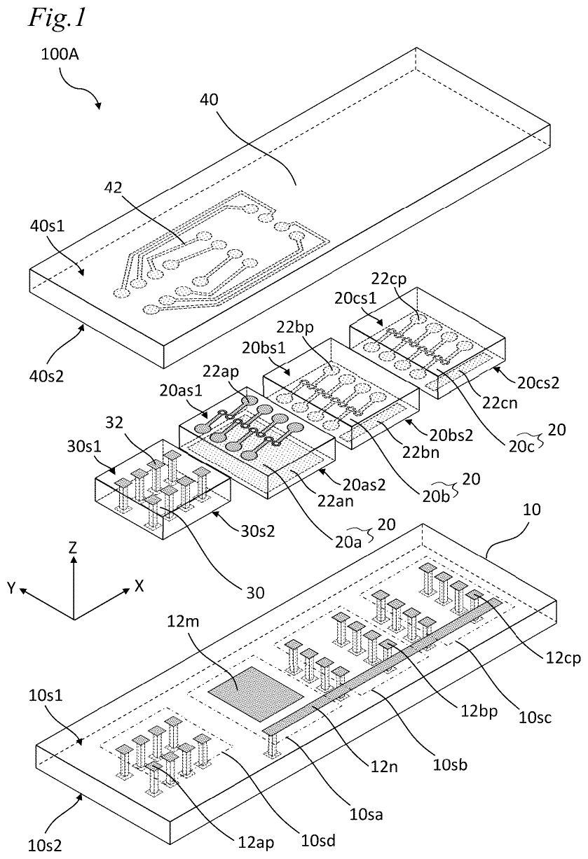

First, with reference to FIG. 1, a configuration example of a light-emitting device according to the first embodiment of the present disclosure will be described. FIG. 1 is an exploded perspective view schematically illustrating the configuration of the light-emitting device according to the exemplary first embodiment of the present disclosure. An X-axis, a Y-axis, and a Z-axis that are orthogonal to each other in the drawings are schematically illustrated for reference. A direction in which an arrow on the X-axis points is referred to as a +X direction, and a direction opposite thereto is referred to as a −X direction. When the ±X directions are not distinguished, the ±X directions are simply referred to as X directions. The same applies to ±Y directions and ±Z directions. Further, in FIG. 1, members provided on an upper surface of each component are represented by solid lines and thick hatching, and members provided inside or on a lower surface of each component are represented by broken lines and thin hatching.

A light-emitting device 100A illustrated in FIG. 1 includes a substrate 10 having an upper surface 10s1 and a lower surface 10s2, three VCSEL elements 20 configured to perform top emission, an intermediate conductive component 30, and a light-transmissive member 40) having an upper surface 40s1 and a lower surface 40s2. Each of the upper surface 10s1 and the lower surface 10s2 of the substrate 10 and the upper surface 40s1 and the lower surface 40s2 of the light-transmissive member 40 is parallel to the XY plane. The lower surface 40s2 of the light-transmissive member 40 faces the upper surface 10s1 of the substrate 10. The three VCSEL elements 20 and the intermediate conductive component 30 are disposed between the upper surface 10s1 of the substrate 10 and the lower surface 40s2 of the light-transmissive member 40). In this specification, a direction normal to the upper surface 10s1 of the substrate 10 is referred to as “upward,” and viewing in a direction normal to the upper surface 10s1 is referred to as a “top view.” In this specification, “parallel” encompasses not only a case of being strictly parallel but also a case of having a deviation of an angle of −5° or greater and 5° or less.

The VCSEL element 20 is an example of the surface emitting laser element configured to perform top emission. The surface emitting laser element has an upper surface, and laser light is emitted upward from at least a part of the upper surface. Other than the VCSEL element 20, the surface emitting laser element may be, for example, a photonic crystal surface emitting laser element. Alternatively, the surface emitting laser element may include an edge-emission type semiconductor laser element, an optical member (for example, a mirror member), and a housing that accommodates them. The edge-emission type semiconductor laser element emits laser light in a direction parallel to the XY plane, for example. The optical member causes the laser light to travel upward. As a result, the laser light traveling upward is emitted from the upper surface of the housing.

The substrate 10 includes a plurality of internal conductive members electrically connected to an external power supply device. The three VCSEL elements 20 include a first VCSEL element 20a to which power is supplied from the upper surface, and a second VCSEL element 20b and a third VCSEL element 20c to which power is supplied from the lower surface. The intermediate conductive component 30 is used to supply power to the first VCSEL element 20a. The light-transmissive member 40 includes a conductive member that electrically connects the intermediate conductive component 30 and the first VCSEL element 20a.

Unlike the light-emitting device 100A according to the first embodiment, a configuration in which the internal conductive member in the substrate 10 and the upper surface of the first VCSEL element 20a are electrically connected via a wire and power is supplied to the first VCSEL element 20a is conceivable. In such a configuration, it is necessary to increase an interval between the upper surface 10s1 of the substrate 10 and the lower surface 40s2 of the light-transmissive member 40 or to provide a conductive region for connecting the wire so that the wire and the lower surface 40s2 of the light-transmissive member 40 do not come into contact with each other. In contrast, in the light-emitting device 100A according to the first embodiment, the intermediate conductive component 30 is used instead of the wire to supply power to the first VCSEL element 20a. Accordingly, the interval between the upper surface 10s1 of the substrate 10 and the lower surface 40s2 of the light-transmissive member 40 can be reduced, and necessity of providing the conductive member region for connecting the wire can be eliminated.

Thus, the light-emitting device 100A can be reduced in size in the Z direction.

The number of the VCSEL elements 20, an oscillation wavelength of each VCSEL element 20, the number and arrangement of light-emitting regions in each VCSEL element 20, the number, arrangement, and shape of electrodes in each VCSEL element 20, the number, arrangement, and shape of conductive members in the substrate 10, and the number, arrangement, and shape of conductive members in the light-transmissive member 40 described below are all examples. The number of the VCSEL elements 20 may be one or more. When a plurality of the VCSEL elements 20 are employed, the oscillation wavelengths of the plurality of VCSEL elements 20 may be different from each other, all the oscillation wavelengths of the plurality of VCSEL elements 20 may be the same, or some of the oscillation wavelengths of the plurality of VCSEL elements 20 may be the same. The number of light-emitting regions in each VCSEL element 20 may be one or more. When the number of the light-emitting regions is plural, the plurality of light-emitting regions may be one-dimensionally or two-dimensionally disposed along the upper surface 10s1 of the substrate 10. A relationship of positive and negative of the electrodes and the conductive members may be reversed.

Each of the components will be described in detail below.

### Substrate 10

The substrate 10 has the upper surface 10s1. The upper surface 10s1 of the substrate 10 includes a first region 10sa for disposing the first VCSEL element 20a and a fourth region 10sd for disposing the intermediate conductive component 30. The upper surface 10s1 may further include a second region 10sb for disposing the second VCSEL element 20b. The upper surface 10s1 may even further include a third region 10sc for disposing the third VCSEL element 20c. The fourth region 10sd is smaller than the first region 10sa. The fourth region 10sd is smaller than the second region 10sb. The fourth region 10sd is smaller than the third region 10sc. The dash-dot lines illustrated in FIG. 1 indicate these regions 10sa, 10sd, 10sb, and 10sc. The fourth region 10sd, the first region 10sa, and the second region 10sb are positioned in this order along the +X direction. The second region 10sb and the third region 10sc are positioned in this order along the +X direction.

The substrate 10 includes positive conductive members (for example, a first positive conductive member 12ap and a second positive conductive member 12bp) for supplying power to the VCSEL elements 20. In addition, the substrate 10 includes a plurality of positive conductive members for supplying power to the VCSEL elements 20. The substrate 10 includes the number of positive conductive members corresponding to the number of light-emitting regions of the VCSEL elements 20. In the example illustrated in FIG. 1, the substrate 10 includes eight first positive conductive members 12ap for supplying power to the first VCSEL element 20a, eight second positive conductive members 12bp for supplying power to the second VCSEL element 20b, and eight third positive conductive members 12cp for supplying power to the third VCSEL element 20c. However, the numbers of the first positive conductive members 12ap, the second positive conductive members 12bp, and the third positive conductive members 12cp are not limited to these, and the substrate 10 can include one or more first positive conductive members 12ap, one or more second positive conductive members 12bp, and one or more third positive conductive members 12cp. Hereinafter, in a description common to all of the first positive conductive member 12ap, the second positive conductive member 12bp, and the third positive conductive member 12cp, they will be simply referred to as the “positive conductive member.”

The substrate 10 has the lower surface 10s2. The positive conductive member includes a portion extending along the Z direction from the upper surface 10s1 to the lower surface 10s2. The positive conductive member is exposed on each of the upper surface 10s1 and the lower surface 10s2 of the substrate 10, and these exposed portions are connected to the portion extending along the Z direction. The first positive conductive member 12ap is exposed in the fourth region 10sd of the upper surface 10s1. The second positive conductive member 12bp is exposed in the second region 10sb of the upper surface 10s1. The third positive conductive member 12cp is exposed in the third region 10sc of the upper surface 10s1. All of the first positive conductive members 12ap are exposed in the fourth region 10sd, all of the second positive conductive members 12bp are exposed in the second region 10sb, and all of the third positive conductive members 12cp are exposed in the third region 10sc.

The plurality of first positive conductive members 12ap are disposed in a matrix in the top view viewed from a position located further in the +Z direction. The same applies to the second positive conductive members 12bp and the third positive conductive members 12cp. In the example illustrated in FIG. 1, the eight first positive conductive members 12ap are arranged in two rows and four columns in the fourth region 10sd on the substrate 10. In the present disclosure, the row direction is parallel to the X direction, and the column direction is parallel to the Y direction. The eight second positive conductive members 12bp are arranged in four rows and two columns in the second region 10sb. The eight third positive conductive members 12cp are arranged in four rows and two columns in the third region 10sc.

The second positive conductive member 12bp in the first column, the second positive conductive member 12bp in the second column, and the third positive conductive member 12cp in the first column are positioned in this order along the +X direction. A distance between the second positive conductive member 12bp and the third positive conductive member 12cp adjacent to each other in the row direction is smaller than a distance between two second positive conductive members 12bp adjacent to each other in the row direction. Furthermore, the third positive conductive member 12cp in the first column and the third positive conductive member 12cp in the second column are positioned in this order along the +X direction. A distance between the second positive conductive member 12bp and the third positive conductive member 12cp adjacent to each other in the row direction is smaller than a distance between the two third positive conductive members 12cp adjacent to each other in the row direction. With this arrangement of the second positive conductive members 12bp and the third positive conductive members 12cp, it is possible to reduce the size of the light-emitting device 100A in the X direction.

Further, a distance between the second positive conductive members 12bp adjacent to each other in the column direction is smaller than a distance between the second positive conductive members 12bp adjacent to each other in the row direction. A distance between the third positive conductive members 12cp adjacent to each other in the column direction is smaller than a distance between the third positive conductive members 12cp adjacent to each other in the row direction. A distance between the first positive conductive members 12ap adjacent to each other in the column direction is equal to or greater than a distance between the first positive conductive members 12ap adjacent to each other in the row direction. A distance between the first positive conductive members 12ap adjacent to each other in the row direction is preferably smaller than a distance between the first positive conductive members 12ap adjacent to each other in the column direction in terms of reducing the size of the light-emitting device 100A.

The substrate 10 includes a negative conductive member 12n for supplying power to the VCSEL element 20. The substrate 10 includes a single negative conductive member 12n common to the first VCSEL element 20a and the second VCSEL element 20b. The negative conductive member 12n is also common to the third VCSEL element 20c. The negative conductive member 12n includes a portion extending along the Z direction from the upper surface 10s1 to the lower surface 10s2. The negative conductive member 12n is exposed on each of the upper surface 10s1 and the lower surface 10s2 of the substrate 10, and these exposed portions are connected to the portion extending along the Z direction. The negative conductive member 12n is exposed in a region for disposing the VCSEL element 20. The negative conductive member 12n extends along the X direction in the top view viewed from a position located further in the +Z direction and is positioned over the first region 10sa and the second region 10sb. The negative conductive member 12n is further positioned over the third region 10sc in the top view as seen from a position located further in the +Z direction. The portion where the negative conductive member 12n is exposed from the lower surface 10s2 of the substrate 10 is positioned immediately below the region where the VCSEL element 20 is disposed. In the example illustrated in FIG. 1, in the substrate 10, it is located immediately below the first region 10sa. The positive conductive member is not provided in the first region 10sa. This arrangement allows the part of the negative conductive member 12n extending from the upper surface 10s1 to the lower surface 10s2 in the Z direction to be located immediately below the first region 10sa, and thus risk of occurrence of a current leakage can be reduced. It may be located directly below the second region 10sb or directly below the third region 10sc instead of directly below the first region 10sa. Each first positive conductive member 12ap, each second positive conductive member 12bp, each third positive conductive member 12cp, and the negative conductive member 12n are electrically connected to the external power supply device.

The substrate 10 further includes a metal film 12m on the upper surface 10s1. The metal film 12m is not exposed on the lower surface 10s2 of the substrate 10. The metal film 12m is provided in the first region 10sa. In the top view as seen from a position located further in the +Z direction, the metal film 12m is provided between the first positive conductive member 12ap and the second positive conductive member 12bp. The number of the metal films 12m is smaller than the number of the first positive conductive members 12ap. The number of the metal films 12m may be one. The metal film 12m may be provided so as to be connected to the negative conductive member 12n. In the top view as seen from a position located further in the +Z direction, an area of the metal film 12m is larger than an area of the positive conductive member.

The first VCSEL element 20a is bonded to the metal film 12m and the negative conductive member 12n of the substrate 10. The first VCSEL element 20a is bonded to a part of the negative conductive member 12n. The first VCSEL element 20a and the substrate 10 may be bonded via a bonding member. The intermediate conductive component 30 is bonded to the first positive conductive member 12ap of the substrate 10. The intermediate conductive component 30 and the substrate 10 may be bonded via the bonding member. The second VCSEL element 20b is bonded to the second positive conductive member 12bp and the negative conductive member 12n of the substrate. The second VCSEL element 20b is bonded to another part of the negative conductive member 12n. The second VCSEL element 20b and the substrate 10 may be bonded via the bonding member. The third VCSEL element 20c is bonded to the third positive conductive member 12cp and the negative conductive member 12n of the substrate 10. The third VCSEL element 20c is bonded to still another part of the negative conductive member 12n. The third VCSEL element 20c and the substrate 10 may be bonded via the bonding member.

The substrate 10 may have a rectangular, circular, or elliptical flat plate shape as a whole, for example. In the substrate 10, the conductive members 12ap, 12bp, 12cp, and 12n may be formed of, for example, at least one metal selected from the group consisting of Ag, Cu, W, Au, Ni, Pt, and Pd. A part of the substrate 10 other than the conductive member 12ap, 12bp, 12cp, or 12n, or the metal film 12m may be formed of, for example, a ceramic containing at least one selected from the group consisting of AlN, SiC, SiN, and alumina.

A thermal conductivity of the part of the substrate 10 other than the conductive member 12ap, 12bp, 12cp, or 12n, or the metal film 12m may be, for example, in a range from 1 W/m·K to 500 W/m·K. The portion having such a thermal conductivity can efficiently transfer heat generated from the VCSEL element 20 to the outside. The dimension of the substrate 10 in the X direction may be, for example, in a range from 0.5 mm to 100 mm, the dimension thereof in the Y direction may be, for example, in a range from 0.5 mm to 50 mm, and the dimension thereof in the Z direction may be, for example, in a range from 0.3 mm to 3.0 mm.

### VCSEL Element 20

The VCSEL element 20 includes one or more light-emitting regions. Each of the plurality of VCSEL elements 20 may include a plurality of the light-emitting regions. In the example illustrated in FIG. 1, each of the three VCSEL elements 20 includes the plurality of light-emitting regions, and the number of the light-emitting regions is eight. The plurality of light-emitting regions of the VCSEL elements 20 are spaced apart from each other along the Y direction. The VCSEL element 20 has upper surfaces 20as1, 20bs1, and 20cs1 facing the lower surface 40s2 of the light-transmissive member 40 and lower surfaces 20as2, 20bs2, and 20cs2 facing the upper surface 10s1 of the substrate 10. The VCSEL element 20 includes positive electrodes 22ap, 22bp, and 22cp and negative electrodes 22an, 22bn, and 22cn. The VCSEL element 20 includes a negative electrode 22an on the lower surface 20as2.

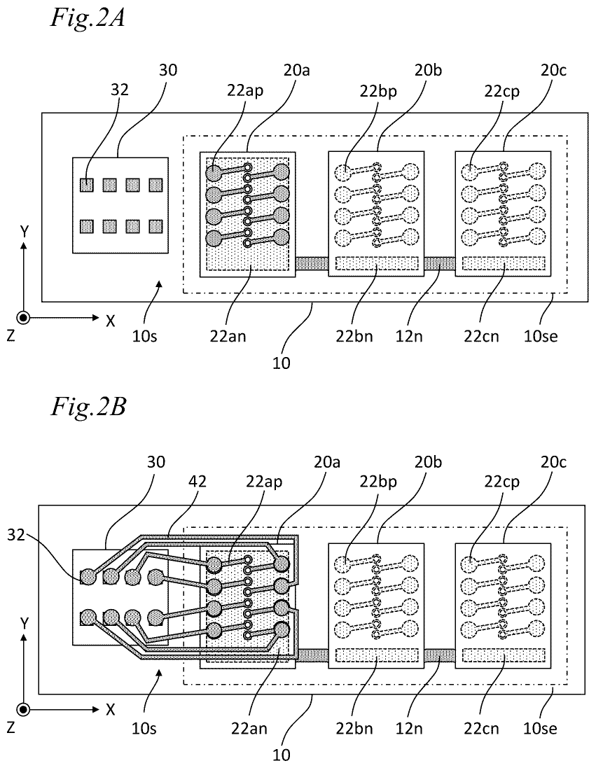

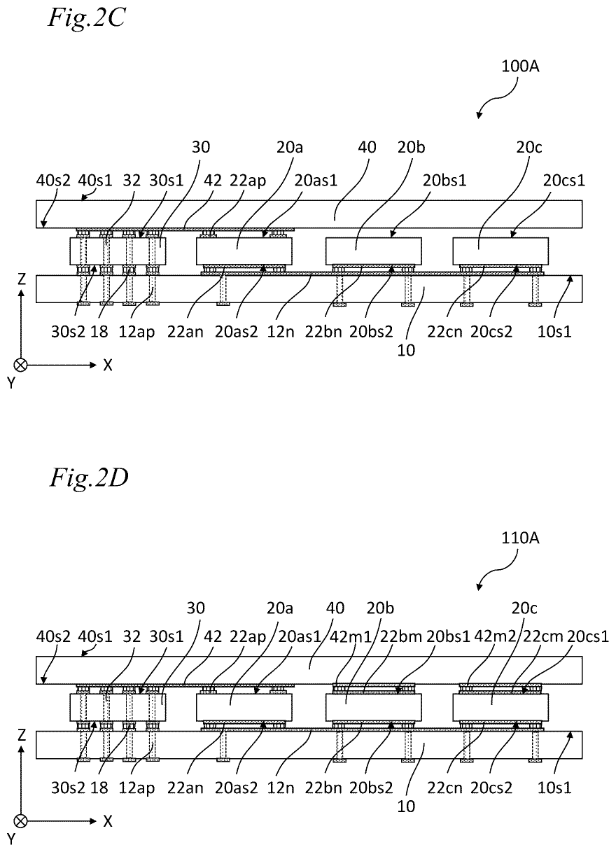

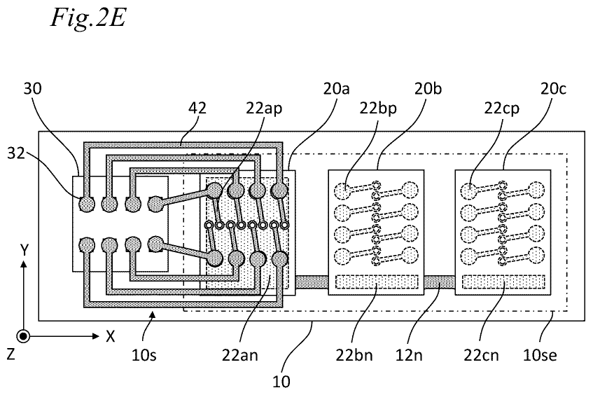

The first VCSEL element 20a emits first laser light having a first oscillation wavelength from each light-emitting region (hereinafter referred to as a first light-emitting region). For example, the first laser light is red light having an oscillation wavelength in a range from 605 nm to 750 nm. The first laser light is emitted in the +Z direction from a part of the upper surface 20as1. The first VCSEL element 20a includes first positive electrodes 22ap, each corresponding to a respective one of the first light-emitting regions for emitting the first laser light from the first light-emitting regions, on a side facing the lower surface 40s2 of the light-transmissive member 40. In the illustrated example, the first positive electrodes 22ap are located at the upper surface 20as1. The negative electrode 22an is provided at the lower surface 20as2. An area of the negative electrode 22an is larger than areas of the negative electrodes 22bn and 22cn, which facilitates not only supplying power to the first VCSEL element 20a but also efficiently transferring the heat generated from the first VCSEL element 20a during driving to the substrate 10. An end portion (for example, a portion represented by a circle in FIG. 2A) of the first positive electrode 22ap located at a position away from the first light-emitting region in the X direction is a portion bonded to a patterned conductive member 42 of the light-transmissive member 40. The end portions of the plurality of first positive electrodes 22ap are positioned such that the first light-emitting region is located therebetween. The end portions of the respective first positive electrodes 22ap are arranged in a matrix. In the example illustrated in FIG. 1, in the first VCSEL element 20a, the end portions of the plurality of first positive electrodes 22ap are arranged in four rows and two columns, and the eight first light-emitting regions are positioned between the two columns in the top view: In the example illustrated in FIG. 1, the end portions of the plurality of first positive electrodes 22ap positioned in the first column and the end portions of the plurality of first positive electrodes 22ap positioned in the second column are in an arrangement relationship in which they are shifted in parallel to one another along the X direction, but are not limited thereto. The end portions of the plurality of first positive electrodes 22ap may be in an arrangement relationship in which the end portions of the plurality of first positive electrodes 22ap positioned in the first column or the second column are shifted along the Y direction from the example illustrated in FIG. 1. The shift amount may be, for example, half of a distance between centers of the two end portions adjacent to each other in the Y direction. By individually controlling the power supply to each of the first positive electrodes 22ap, the first laser light can be emitted from the plurality of first light-emitting regions simultaneously or at different timings. When the first laser lights are to be simultaneously emitted from the respective first light-emitting regions, the VCSEL element including the single first positive electrode 22ap electrically connected to each of the first light-emitting regions may be used.

The second VCSEL element 20b emits second laser light having a second oscillation wavelength from each light-emitting region (hereinafter referred to as a second light-emitting region). For example, the second laser light is green light having an oscillation wavelength in a range from 495 nm to 570 nm. The second laser light is emitted in the +Z direction from a part of an upper surface 20bs1. The second VCSEL element 20b includes second positive electrodes 22bp, each corresponding to a respective one of second light-emitting regions for emitting the second laser light from each of the second light-emitting regions, on a side facing the upper surface 10s 1 of the substrate 10, more specifically the lower surface 20bs2. An end portion (for example, a portion represented by a circle in FIG. 2A) of the second positive electrode 22bp provided at a position away from the second light-emitting region in the X direction is a portion bonded to the positive conductive member of the substrate 10. The end portions of the respective second positive electrodes 22bp are arranged in a matrix. The end portions of the plurality of second positive electrodes 22bp are arranged in a matrix of rows and columns of the same numbers as the number of rows and the number of columns of the end portions of the plurality of first positive electrodes 22ap. In the example illustrated in FIG. 1, in the second VCSEL element 20b, the end portions of the plurality of second positive electrodes 22bp are arranged in four rows and two columns, and the eight second light-emitting regions are positioned between the two columns in the top view: Thus, the power supply to each second positive electrode 22bp can be individually controlled. A VCSEL element including a single second positive electrode 22bp electrically connected to the second light-emitting regions may be used. An arrangement relationship of the end portions of the plurality of second positive electrodes 22bp positioned in the first column and the second column is similar to an arrangement relationship of the end portions of the plurality of first positive electrodes 22ap positioned in the first column and the second column.

The third VCSEL element 20c emits third laser light having a third oscillation wavelength from each light-emitting region (hereinafter referred to as a third light-emitting region). For example, the third laser light is blue light having an oscillation wavelength in a range from 420 nm to 494 nm. The third laser light is emitted in the +Z direction from a part of the upper surface 20cs1. The arrangement of the positive electrodes in the third VCSEL element 20c is the same as that described for the second VCSEL element 20b.

The first positive conductive members 12ap electrically connected to the first VCSEL element 20a and provided on the substrate 10 are not provided on the second VCSEL element 20b side with respect to the first VCSEL element 20a. With the arrangement in which the first positive conductive members 12ap are not provided between the first VCSEL element 20a and the second VCSEL element 20b, the distance between the VCSEL elements can be reduced.

In the example illustrated in FIG. 1, the upper surfaces 20as1, 20bs1, and 20cs1 and the lower surfaces 20as2, 20bs2, and 20cs2 of the VCSEL elements 20 are represented as planes parallel to the XY plane, but may actually have irregularities. Although the dimensions of the three VCSEL elements 20 in the Z direction are all the same, they may be different from one another, or the dimensions of the two VCSEL elements 20 among the three VCSEL elements 20 in the Z direction may be the same as each other.

The light-emitting region of each VCSEL element 20 is positioned inside each VCSEL element 20, as will be described later. The first VCSEL element 20a that emits the first laser light is mounted on the upper surface 10s1 of the substrate 10 in a so-called face-up manner in which the first light-emitting region is positioned closer to the upper surface 20as1 than to the lower surface 20as2. The second VCSEL element 20b that emits the second laser light is mounted on the upper surface 10s1 of the substrate 10 in a so-called face-down manner in which the second light-emitting region is positioned closer to the lower surface 20bs2 than to the upper surface 20bs1. The same applies to the third VCSEL element 20c that emits the third laser light as the second VCSEL element 20b.

In the light-emitting device 100A according to the first embodiment, the three VCSEL elements 20) are driven independently from each other, so that laser light having one or more oscillation wavelengths can be selected among three oscillation wavelengths different from one another and can be emitted from the upper surface 40s1 of the light-transmissive member 40. Further, white laser light can be obtained by mixing the laser lights having these three oscillation wavelengths. The first oscillation wavelength may be an oscillation wavelength longer than the second oscillation wavelength. For example, the first oscillation wavelength is in a range from 605 nm to 750 nm and preferably in a range from 610 nm to 700 nm. For example, the second oscillation wavelength is in a range from 495 nm to 570 nm and preferably in a range from 510 nm to 550 nm. For example, the third oscillation wavelength is in a range from 420 nm to 494 nm and preferably in a range from 440 nm to 475 nm. When the light-emitting device 100A is used as, for example, a light source of a display, an output of laser light emitted from each of the VCSEL elements 20 may be, for example, in a range from 0.1 mW to 100 mW. When the output of the laser light emitted from the light-emitting device 100A satisfies an output of class 1 in the safety standard for laser products according to JIS C 6802, the safety of the light-emitting device 100A can be improved.

The dimension of each of the VCSEL elements 20 in each of the X direction and the Y direction may be, for example, in a range from 0.2 mm to 3 mm, and the dimension in the Z direction may be, for example, in a range from 0.01 mm to 1 mm. The number of positive electrodes in each VCSEL element 20 is one or more. One or more positive electrodes may be constituted of, for example, a plurality of positive electrodes for emission of laser light from a plurality of light-emitting regions. The configuration and materials of each VCSEL element 20) will be described in detail later.

### Intermediate Conductive Component 30

The intermediate conductive component 30 has an upper surface 30s1 facing the lower surface 40s2 of the light-transmissive member 40 and a lower surface 30s2 facing the upper surface 10s1 of the substrate 10, and includes one or more intermediate conductive members 32. The intermediate conductive component 30 includes the intermediate conductive members 32 the number of which is equal to or more than the number of the first positive electrodes 22ap of the first VCSEL element. In the example illustrated in FIG. 1, the intermediate conductive component 30 includes a plurality of the intermediate conductive members 32, and the number thereof is eight. Each intermediate conductive member 32 includes a portion extending in the Z direction from the upper surface 30s1 to the lower surface 30s2. The intermediate conductive member 32 is exposed on each of the upper surface 30s1 and the lower surface 30s2 of the intermediate conductive component 30, and these exposed portions are connected to the portion extending along the Z direction.

The intermediate conductive component 30 may have a rectangular, circular, or elliptical flat plate shape as a whole, for example. A material of the intermediate conductive member 32 of the intermediate conductive component 30 may be, for example, the same as the material of the conductive member 12ap, 12bp, 12cp, and 12n of the substrate 10. The material of the part of the intermediate conductive component 30 other than the intermediate conductive member 32 may be, for example, the same as the material of the part of the substrate 10 other than the conductive member 12ap, 12bp, 12cp, or 12n, or the metal film 12m. A dimension in each of the X direction and the Y direction of the intermediate conductive component 30 may be in a range from 0.2 mm to 3 mm, for example. For example, the dimension of the intermediate conductive component 30 in the X direction may be in a range from 0.5 times to 1.5 times the dimension of the first VCSEL element 20a in the Y direction. For example, the dimension of the intermediate conductive component 30 in the Y direction may be in a range from 0.5 times to 1.5 times the dimension of the first VCSEL element 20a in the X direction. For example, the dimension of the intermediate conductive component 30 in the Z direction may be in a range from 0.8 times to 1.2 times the dimension of the first VCSEL element 20a in the Z direction. In this case, with reference to the upper surface 10s1 of the substrate 10, a height of the upper surface 30s1 of the intermediate conductive component 30 can be made substantially equal to a height of the upper surface 20as1 of the first VCSEL element 20a. An effect obtained by this configuration will be described below.

### Light-Transmissive Member 40

The light-transmissive member 40 transmits the laser light emitted from the VCSEL element 20. In the example illustrated in FIG. 1, the light-transmissive member 40 transmits the first laser light, the second laser light, and the third laser light. The light-transmissive member 40) has a light incident surface in a part of the lower surface 40s2, and the laser light emitted from each of the VCSEL elements 20 is incident on the light incident surface. The light-transmissive member 40 further has a light-emitting surface in a part of the upper surface 40s1, and the light-emitting surface is positioned on the side opposite to the light incident surface and emits the laser light. The light incident surface and the light-emitting surface are surfaces parallel to each other and parallel to the XY plane. A flatness of each of the light incident surface and the light-emitting surface may be, for example, 0.01 mm or less. An antireflection film may be provided on the light incident surface and/or the light-emitting surface.

The light-transmissive member 40 includes one or more patterned conductive members 42 on the lower surface 40s2. The light-transmissive member 40 includes the pattern conductive members 42 the number of which is equal to or more than the number of the first positive electrodes 22ap of the first VCSEL element. One end of the patterned conductive member 42 is bonded to the first positive electrode 22ap, and the other end thereof is bonded to the intermediate conductive member 32. In the example illustrated in FIG. 1, the light-transmissive member 40) includes a plurality of the patterned conductive members 42, and the number of the patterned conductive members 42 is eight. Each of the eight patterned conductive members 42 is electrically connected to a respective one of eight first positive conductive members 12ap of the substrate 10 by a respective one of the eight intermediate conductive members 32 of the intermediate conductive component 30. Each of the eight patterned conductive members 42 is further electrically connected to a respective one of eight first positive electrodes 22ap in the first VCSEL element 20a. As described above, the height from the upper surface 10s1 of the substrate 10 to the upper surface 30s1 of the intermediate conductive component 30 may be substantially the same as the height from the upper surface 10s1 of the substrate 10 to the upper surface 20as1 of the first VCSEL element 20a. By employing such a configuration, the intermediate conductive member 32 of the intermediate conductive component 30) and the first positive electrode 22ap of the first VCSEL element 20a are easily electrically connected to each other by the patterned conductive member 42 of the light-transmissive member 40.

The light-transmissive member 40 may have a rectangular, circular, or elliptical flat plate shape as a whole, for example. The light-transmissive member 40 may be formed of, for example, at least one selected from the group consisting of glass, quartz, synthetic quartz, sapphire, ceramic, and plastic. The light-transmissive member 40 may have transmissivity across its entirety. Alternatively, the light-transmissive member 40 may have a configuration in which a portion through which each of the first laser light, the second laser light, and the third laser light is to pass is transmissive of light and a part or all of the remaining portion does not transmit light. In the light-transmissive member 40, transmittance of the portion having the transmissivity may be, for example, 60% or more, preferably 70% or more, and more preferably 80% or more with respect to incident laser light. For example, dimensions in the X direction and the Y direction of the light-transmissive member 40 are equal to the dimensions in the X direction and the Y direction of the substrate 10, respectively. The dimension in the Z direction of the light-transmissive member 40 may be in a range from 0.1 mm to 2.0 mm, for example.

The patterned conductive member 42 can be formed by, for example, providing a metal film on the lower surface 40s2 of the light-transmissive member 40. For example, the patterned conductive member 42 can be formed by patterning the metal film into a desired pattern. The patterning may be performed, for example, by etching. A material of the patterned conductive member 42 may be, for example, the same as the material of the conductive members 12ap, 12bp, 12cp, and 12n of the substrate 10.

In this specification, the conductive member 12ap and the conductive member 12bp in the substrate 10 are also referred to as a “first conductive member” and a “second conductive member,” respectively, the patterned conductive member 42 in the light-transmissive member 40 is also referred to as a “third conductive member,” and the conductive member 12cp in the substrate 10 is also referred to as a “fourth conductive member.”

Subsequently, electrical connection of the first positive electrode 22ap of the first VCSEL element 20a to the first positive conductive member 12ap of the substrate 10 will be described with reference to FIGS. 2A and 2C. FIG. 2A is a top view schematically illustrating the substrate 10, the three VCSEL elements 20, and the intermediate conductive component 30 in the light-emitting device 100A illustrated in FIG. 1. FIG. 2B is a top view schematically illustrating the patterned conductive member 42 in addition to the configuration illustrated in FIG. 2A. FIG. 2C is a side view of the light-emitting device 100A illustrated in FIG. 1 when seen from the −Y direction side.

A region surrounded by a dash-dot line illustrated in FIG. 2A represents an element region 10se in the upper surface 10s1 of the substrate 10. The element region 10se is a region surrounded by a plurality of imaginary straight lines and includes regions where the three VCSEL elements 20 are disposed in the top view: Each straight line and the VCSEL element 20 closest to the straight line are separated by a constant distance. The constant distance is, for example, a half of a minimum gap of intervals formed between two VCSEL elements 20 adjacent to each other of the three VCSEL elements. The interval is smaller than a width of the intermediate conductive component 30 in the X direction. The three VCSEL elements 20 are disposed inside the element region 10se. On the other hand, the intermediate conductive component 30 is disposed outside the element region 10se.

With an arrangement in which the intermediate conductive component 30 is not disposed between the VCSEL elements 20, the interval between the VCSEL elements 20 can be reduced. In the example illustrated in FIG. 2A, the light-emitting device 100A may include one VCSEL element 20 in addition to the three VCSEL elements 20 to include the four VCSEL elements.

As illustrated in FIG. 2B, the patterned conductive member 42 is provided so as not to overlap with the light-emitting region in each of the VCSEL elements 20 in the top view. Therefore, each patterned conductive member 42 does not obstruct the travel of the laser light emitted from each VCSEL element 20. Each of the patterned conductive members 42 includes an end positioned on the +X direction side and an end positioned on the −X direction side. The end positioned on the +X direction side is electrically connected to the first positive electrode 22ap illustrated in FIG. 2A in the first VCSEL element 20a. The end positioned on the −X direction side is electrically connected to the intermediate conductive member 32 illustrated in FIG. 2A in the intermediate conductive component 30.

In the example illustrated in FIG. 2B, the eight patterned conductive members 42 include four first patterned conductive members, each electrically connected to a respective one of four first positive electrodes 22ap in the first column positioned on the −X direction side, and four second patterned conductive members, each electrically connected to a respective one of four first positive electrodes 22ap in the second column positioned on the +X direction side. Each of the four second patterned conductive members passes through the outside the four first patterned conductive members so as to bypass the light-emitting region in the first VCSEL element 20a in the top view: The outside of the four first patterned conductive members refers to the +Y direction side or the −Y direction side with respect to the four first patterned conductive members.

Each of the eight patterned conductive members 42 includes a portion overlapping with the first negative electrode 22an in the top view: Each of the eight patterned conductive members 42 does not overlap with any part of the second VCSEL element 20b or the third VCSEL element 20c in the top view: Among the intermediate conductive members 32, the intermediate conductive member 32 electrically connected to the second patterned conductive member is positioned farther from the first VCSEL element 20a than the intermediate conductive member 32 electrically connected to the first patterned conductive member is. In the top view; at least one second patterned conductive member passes through a region between the first VCSEL element 20a and the second VCSEL element 20b. At least one second patterned conductive member includes a portion overlapping with the conductive member 12n of the substrate 10 in the top view:

As illustrated in FIG. 2C, the lower portions of the intermediate conductive members 32 of the intermediate conductive component 30 are electrically connected to respective first positive conductive members 12ap of the substrate 10, and the upper portions of the intermediate conductive member 32 are electrically connected to respective patterned conductive members 42 of the light-transmissive member 40. The electrical connection is established by bump connection of a bonding member 18 containing a metal material, such as Au. Similarly, the first positive electrodes 22ap of the first VCSEL element 20a are electrically connected to respective patterned conductive members 42 of the light-transmissive member 40. The first negative electrode 22an of the first VCSEL element 20a is electrically connected to the negative conductive member 12n of the substrate 10. The first negative electrode 22an of the first VCSEL element 20a is further bonded to the metal film 12m of the substrate 10 illustrated in FIG. 1 by bump connection of a bonding member containing a metal material, such as Au. Alternatively, since the first negative electrode 22an of the first VCSEL element 20a has a large area as described above, it may be bonded to the metal film 12m in the substrate 10 illustrated in FIG. 1 via a conductive bonding material, such as an Ag paste or AnSn.

The second negative electrode 22bn in the second VCSEL element 20b is electrically connected to the negative conductive member 12n in the substrate 10, and the third negative electrode 22cn in the third VCSEL element 20c is electrically connected to the negative conductive member 12n in the substrate 10. The second positive electrodes 22bp of the second VCSEL element 20b are electrically connected to respective second positive conductive members 12bp of the substrate 10. Similarly, the third positive electrodes 22cp of the third VCSEL element 20c are electrically connected to respective third positive conductive members 12cp of the substrate 10.

As illustrated in FIG. 2C, the light-transmissive member 40 is supported by the first VCSEL element 20a and the intermediate conductive component 30. Therefore, it is not necessary to additionally provide a lateral wall for supporting the light-transmissive member 40. However, such a lateral wall may be provided additionally. Furthermore, the three VCSEL elements 20 may be hermetically sealed by the substrate 10 and the light-transmissive member 40 in addition to the lateral wall. The hermetic sealing can improve the durability of the three VCSEL elements 20.

In the example illustrated in FIG. 2C, the dimensions of the second VCSEL element 20b and the third VCSEL element 20c in the Z direction are smaller than the interval between the upper surface 10s1 of the substrate 10 and the lower surface 40s2 of the light-transmissive member 40, which is defined by the first VCSEL element 20a and the intermediate conductive component 30. Therefore, the upper surface 20bs1 of the second VCSEL element 20b and the upper surface 20cs1 of the third VCSEL element 20c are not in contact with the lower surface 40s2 of the light-transmissive member 40. As long as the intermediate conductive component 30 can supply power to the first VCSEL element 20a, at least a part of the upper surface 20bs1 of the second VCSEL element 20b and/or the upper surface 20cs1 of the third VCSEL element 20c may be in contact with the lower surface 40s2 of the light-transmissive member 40).

Subsequently, a modified example of the light-emitting device 100A according to the first embodiment will be described with reference to FIG. 2D. FIG. 2D is a side view schematically illustrating the modified example of the light-emitting device 100A according to the first embodiment. A light-emitting device 110A illustrated in FIG. 2D is different from the light-emitting device 100A illustrated in FIG. 2C in the following configurations. The second VCSEL element 20b includes a metal film 22bm at an upper surface 20sb1, and the third VCSEL element 20c includes a metal film 22cm at an upper surface 20sc1. The metal film 22bm is provided in a region of the upper surface 20sb1 that does not overlap with the second light-emitting region in the top view; and does not interfere with the emission of the second laser light. The metal film 22cm is provided in a region of the upper surface 20sc1 that does not overlap with the third light-emitting region in the top view, and does not interfere with the emission of the third laser light. The light-transmissive member 40 includes a metal film 42m1 facing the metal film 22bm and a metal film 42m2 facing the metal film 22cm on the lower surface 40s2. The metal film 42m1 and the metal film 42m2 in the light-transmissive member 40 are bonded to the metal film 22bm in the second VCSEL element 20b and the metal film 22cm in the third VCSEL element 20c by bump connection of the bonding member 18, respectively. Instead of the metal films 22bm, 22cm, 42m1, and 42m2, a film made of a member other than metal may be provided as long as the bonding strength can be ensured.

In the modified example of the first embodiment, the light-transmissive member 40 is supported not only by the first VCSEL element 20a and the intermediate conductive component 30 but also by the second VCSEL element 20b and the third VCSEL element 20c as illustrated in FIG. 2D. Therefore, the light-transmissive member 40 can be more stably supported.

Subsequently, another modified example of the light-emitting device 100A according to the first embodiment will be described with reference to FIG. 2E. Similarly to the light-emitting device 100A, the another modified example includes the substrate 10, the three VCSEL elements 20, the intermediate conductive component 30, and the light-transmissive member 40. FIG. 2E is a top view schematically illustrating the substrate 10, the three VCSEL elements 20, the intermediate conductive component 30, and the patterned conductive member 42 in the light-emitting device according to the another modified example of the first embodiment. The configuration illustrated in FIG. 2E differs from the configuration illustrated in FIG. 2B in the distribution of the eight light-emitting regions in the first VCSEL element 20a and the shape of the patterned conductive member 42.

In the example illustrated in FIG. 2E, in the first VCSEL element 20a, the eight light-emitting regions are spaced apart from each other not along the Y direction but along the X direction. The end portion of the first positive electrode 22ap is located at a position away from the first light-emitting region in the Y direction. The end portions of the plurality of first positive electrodes 22ap are positioned such that the first light-emitting region is located therebetween. In the first VCSEL element 20a, the end portions of the plurality of first positive electrodes 22ap are arranged in two rows and four columns, and the eight first light-emitting regions are positioned between the two rows in the top view:

In the example illustrated in FIG. 2E, the eight patterned conductive members 42 include four third patterned conductive members, each electrically connected to a respective one of four first positive electrodes 22ap in the first row positioned on the +Y direction side, and four fourth patterned conductive members, each electrically connected to a respective one of four first positive electrodes 22ap in the second row positioned on the −Y direction side. The four third patterned conductive members are further electrically connected to respective ones of four intermediate conductive members 32 in the first row positioned on the +Y direction side in the intermediate conductive component 30. The four fourth patterned conductive members are further electrically connected to respective ones of the four intermediate conductive members 32 in the second row positioned on the −Y direction side in the intermediate conductive component 30.

One third patterned conductive member among the four third patterned conductive members is electrically connected to the first positive electrode 22ap and the intermediate conductive member 32 that are closest to the region between the intermediate conductive component 30 and the first VCSEL element 20a. Another one of the third patterned conductive members is electrically connected to the first positive electrode 22ap and the intermediate conductive member 32 that are the second closest to the region. Still another one of the third patterned conductive members is electrically connected to the first positive electrode 22ap and the intermediate conductive member 32 that are the third closest to the region. The remaining third patterned conductive member is electrically connected to the first positive electrode 22ap and the intermediate conductive member 32 that are fourth closest to the region. In the top view; at least one third patterned conductive member passes through the region between the intermediate conductive component 30 and the first VCSEL element 20a. The electrical connection of the four fourth patterned conductive members is similar to the electrical connection of the four third patterned conductive members.

Not only in the first VCSEL element 20a but also in the second VCSEL element 20b and the third VCSEL element 20c, the eight light-emitting regions may be spaced apart from each other along the X direction instead of along the Y direction. In this case, the eight second positive conductive members 12bp illustrated in FIG. 1 are arranged in two rows and four columns in the second region 10sb, and the eight third positive conductive members 12cp are arranged in two rows and four columns in the third region 10sc.

The bonding relationship between the members in the light-emitting device 100A according to the first embodiment and the above-described two modified examples is as follows. The first VCSEL element 20a is bonded to the substrate 10 via the bonding member. In the example illustrated in FIG. 1, the first negative electrode 22an of the first VCSEL element 20a is bonded to the metal film 12m of the substrate 10 via the bonding member. The first negative electrode 22an in the first VCSEL element 20a is further bonded to a part of the negative conductive member 12n in the substrate 10 via the bonding member 18.

The second VCSEL element 20b is bonded to the substrate 10 via the bonding member. In the example illustrated in FIG. 1, the second positive electrodes 22bp of the second VCSEL element 20b are bonded to respective ones of the second positive conductive members 12bp of the substrate 10 via the bonding member. The second negative electrode 22bn of the second VCSEL element 20b is bonded to another part of the negative conductive member 12n of the substrate 10 via the bonding member.

The third VCSEL element 20c is bonded to the substrate 10 via the bonding member. In the example illustrated in FIG. 1, the third positive electrodes 22cp of the third VCSEL element 20c are bonded to respective ones of the third positive conductive member 12cp of the substrate 10 via the bonding member. The third negative electrode 22cn in the third VCSEL element 20c is bonded to still another part of the negative conductive member 12n in the substrate 10 via the bonding member.

The intermediate conductive component 30 is bonded to the substrate 10 via the bonding member. In the example illustrated in FIG. 1, the intermediate conductive member 32 of the intermediate conductive component 30 is bonded to the first positive conductive member 12ap of the substrate 10 via the bonding member.

The light-transmissive member 40 is bonded to the intermediate conductive component 30 and the first VCSEL element 20a via the bonding member. In the example illustrated in FIG. 1, the patterned conductive member 42 of the light-transmissive member 40 is bonded to the intermediate conductive member 32 of the intermediate conductive component 30 via the bonding member. The patterned conductive member 42 of the light-transmissive member 40 is further bonded to the first positive electrode 22ap of the first VCSEL element 20a via the bonding member.

The light-transmissive member 40 may be further bonded to the second VCSEL element 20b and the third VCSEL element 20c via the bonding member. In the example illustrated in FIG. 2D, the metal film 42m1 in the light-transmissive member 40 is bonded to the metal film 22bm in the second VCSEL element 20b via the bonding member. The metal film 42m2 of the light-transmissive member 40 is bonded to the metal film 22cm of the third VCSEL element 20c via the bonding member.

The light-emitting device 100A according to the first embodiment and the above-described two modified examples include the first VCSEL element 20a that is mounted in a face-up manner. Even when the VCSEL element that is mounted in a face-up manner is provided, supplying power to the first VCSEL element 20a via the intermediate conductive component 30 instead of supplying power via a wire allows for reducing the interval between the upper surface 10s1 of the substrate 10 and the lower surface 40s2 of the light-transmissive member 40, so that the light-emitting device 100A can be reduced in size in the Z direction.

In one example, the light-emitting device includes a plurality of VCSEL elements that are mounted in a face-down manner and does not include a VCSEL element that is mounted in a face-up manner. Some VCSEL elements among the plurality of VCSEL elements may include a positive electrode extending to the upper surface via a lateral surface, for example. Power can be supplied to these VCSEL elements via the intermediate conductive component 30 and the patterned conductive member 42. In such a light-emitting device, it is not necessary to provide the positive conductive member, in the substrate 10, for supplying power to some VCSEL elements directly below the VCSEL elements, and a degree of freedom of the arrangement of the positive conductive member on the substrate 10 can be improved.

### Second Embodiment

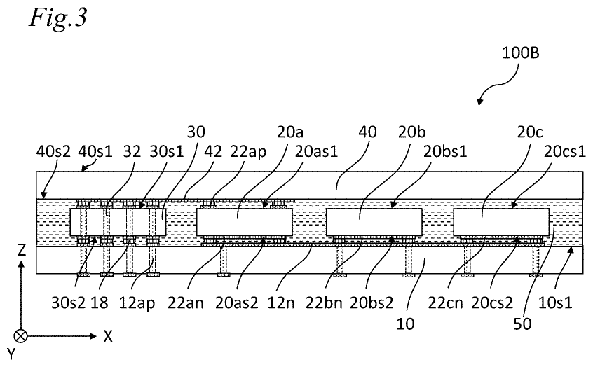

Subsequently, differences from the light-emitting device 100A according to the first embodiment in a configuration example of a light-emitting device 100B according to the second embodiment of the present disclosure will be mainly described with reference to FIG. 3. FIG. 3 is a side view schematically illustrating the configuration of the light-emitting device according to the exemplary second embodiment of the present disclosure when seen from the −Y direction side. The light-emitting device 100B illustrated in FIG. 3 is different from the light-emitting device 100A illustrated in FIG. 2C in that the light-emitting device 100B further includes a resin 50 that fills a gap between the upper surface 10s1 of the substrate 10 and the lower surface 40s2 of the light-transmissive member 40.

### Resin 50

The resin 50 seals the VCSEL element 20 and the intermediate conductive component 30. The resin 50 is provided between the upper surface 10s1 of the substrate 10 and the lower surface 40s2 of the light-transmissive member 40 and is in contact with both of them. Portions of the resin 50 are positioned between the upper surfaces 20as1, 20bs1, and 20cs1 of the VCSEL elements 20 and the lower surface 40s2 of the light-transmissive member 40 and are in contact with each of them. Other portions of the resin 50 are positioned between the lower surfaces 20as2, 20bs2, and 20cs2 of the VCSEL elements 20 and the upper surface 10s1 of the substrate 10 and are in contact with each of them. Still other portions of the resin 50 are in contact with the lateral surfaces of the VCSEL elements 20. The same applies to the positional relationship between the resin 50 and the intermediate conductive component 30. In this manner, the resin 50 is disposed between the substrate 10 and the light-transmissive member 40. The resin 50 may be, for example, a photocurable resin, such as an ultraviolet curable resin or a visible light curable resin, or a thermosetting resin. The resin 50 is cured by irradiation with ultraviolet light or visible light or by heating.

By sealing each VCSEL element 20 with the resin 50, the VCSEL element 20 can be protected from moisture and/or dust, and the durability of the VCSEL element 20 can be improved. Even when an external object collides with the light-transmissive member 40, the impact transmitted to each VCSEL element 20 can be reduced by the resin 50. The resin 50 also serves to support the light-transmissive member 40.

In the light-emitting device 100B according to the second embodiment, the outer lateral surfaces of the light-emitting device 100B are at least partially formed of the resin 50. A molded body sealing the VCSEL element 20 includes the substrate 10, the light-transmissive member 40, and the resin 50. The substrate 10 constitutes a lower surface of the molded body. The resin 50 is included in outer lateral surfaces of the molded body. The light-transmissive member 40 constitutes an upper surface of the molded body. The resin 50 may constitute a part of the lower surface or the upper surface of the molded body, and the substrate 10 or the light-transmissive member 40 may constitute a part of an outer lateral surface of the molded body. It is considered that the light-emitting device 100B according to the second embodiment having the structure in which the VCSEL element as a laser element is sealed using the resin can represent a structural form of a new light-emitting device beyond the idea of a conventional light-emitting device including a laser element.

In the light-emitting device 100B according to the second embodiment, the gap between the upper surface of the VCSEL element 20 and the light incident surface of the light-transmissive member 40 is filled with the resin 50, and the light incident surface and the light-emitting surface of the light-transmissive member 40 are flat surfaces parallel to each other as described above. Therefore, with the light-transmissive member 40 disposed above each VCSEL element 20, deformation in shape of the laser light emitted to the outside from the light-emitting surface of the light-transmissive member 40 can be inhibited without considering the flatness of the surface of the cured resin 50.

From the viewpoint of obtaining the above-described effects by the resin 50 and the light-transmissive member 40, it is sufficient that the light-emitting device 100B according to the second embodiment include at least one VCSEL element 20 among the three VCSEL elements 20. The light-emitting device 100B includes, for example, the first VCSEL element 20a among the three VCSEL elements 20, but need not include the second VCSEL element 20b or the third VCSEL element 20c. Alternatively, the light-emitting device 100B includes, for example, the second VCSEL element 20b and/or the third VCSEL element 20c among the three VCSEL elements 20, but need not include the first VCSEL element 20a. In this case, it is not necessary to provide the intermediate conductive component 30 or the patterned conductive member 42. That is, the light-emitting device 100B includes the substrate 10, the VCSEL elements 20 disposed on the substrate 10, the light-transmissive member 40 disposed above the VCSEL elements 20, and the resin 50 provided at least between the substrate 10 and the light-transmissive member 40.

In the light-emitting device 100B according to the second embodiment, each of the VCSEL elements 20 can be protected or sealed by the resin 50. The light-transmissive member 40 can be supported with the resin 50 disposed therebetween. Therefore, it is not necessary to separately provide lateral walls for hermetically sealing the respective VCSEL elements 20 and supporting the light-transmissive member 40, and thus it is possible to reduce the size of the light-emitting device 100B. Such an effect of reduction in size can also be obtained in the light-emitting device 100B including at least one VCSEL element 20.

The light-emitting device 100B according to the second embodiment can be manufactured by the following manufacturing method, for example. In the first step, the light-emitting device 100A according to the first embodiment is provided. In the subsequent step, an uncured resin is injected between the upper surface 10s1 of the substrate 10 and the lower surface 40s2 of the light-transmissive member 40. In the subsequent step, the resin is cured by irradiation with ultraviolet or visible light or by heating.

A light-emitting device without the first VCSEL element 20a, the intermediate conductive component 30, and the patterned conductive member 42 in the light-emitting device 100B according to the second embodiment can be manufactured by, for example, the following manufacturing method instead of a manufacturing method similar to the manufacturing method described above. In the first step, the substrate 10 and the second VCSEL element 20b and/or the third VCSEL element 20c supported by the upper surface 10s1 of the substrate 10 are provided. In the subsequent step, the second VCSEL element 20b and/or the third VCSEL element 20c are sealed by an uncured resin. In the subsequent step, the light-transmissive member 40) not including the patterned conductive member 42 is disposed on the resin. In the subsequent step, the resin is cured by irradiation with ultraviolet or visible light or by heating.

### Third Embodiment

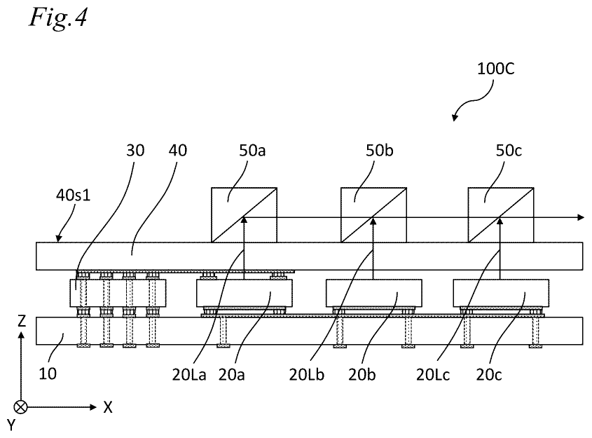

Subsequently, differences from the light-emitting device 100A according to the first embodiment in a configuration example of a light-emitting device 100C according to the third embodiment of the present disclosure will be mainly described with reference to FIG. 4. FIG. 4 is a side view schematically illustrating the configuration of the light-emitting device according to the exemplary third embodiment of the present disclosure when seen from the −Y direction side. The light-emitting device 100C illustrated in FIG. 4 differs from the light-emitting device 100A illustrated in FIG. 2C in that the light-emitting device 100C further includes a first dichroic mirror 50a, a second dichroic mirror 50b, and a third dichroic mirror 50c on the upper surface 40s1 of the light-transmissive member 40. In the top view; the first dichroic mirror 50a, the second dichroic mirror 50b, and the third dichroic mirror 50c overlap with the first VCSEL element 20a, the second VCSEL element 20b, and the third VCSEL element 20c, respectively.

The first dichroic mirror 50a reflects first laser light 20La emitted in the +Z direction from the first VCSEL element 20a in the +X direction. The second dichroic mirror 50b reflects second laser light 20Lb emitted in the +Z direction from the second VCSEL element 20b in the +X direction and transmits the first laser light 20La in the +X direction. The third dichroic mirror 50c reflects third laser light 20Lc emitted in the +Z direction from the third VCSEL element 20c in the +X direction and transmits the first laser light 20La and the second laser light 20Lb in the +X direction. The first laser light 20La, the second laser light 20Lb, and the third laser light 20Lc are coaxially combined by the three dichroic mirrors 50a, 50b, and 50c and then travel in the +X direction.

With the light-emitting device 100C according to the third embodiment, the first laser light 20La, the second laser light 20Lb, and the third laser light 20Lc can be coaxially combined and then travel in a direction different from an upward direction. The light-emitting device 100C may include two dichroic mirrors instead of the three dichroic mirrors 50a. 50b, and 50c. The two dichroic mirrors coaxially combine two laser lights among the first laser light 20La, the second laser light 20Lb, and the third laser light 20Lc and causes the combined laser light to emit in a direction different from an upward direction. The remaining laser light is emitted upward.

Furthermore, the light-emitting device 100C may include a planar lightwave circuit and/or a prism on the upper surface 40s1 of the light-transmissive member 40 instead of the dichroic mirrors 50a, 50b, and 50c. The planar lightwave circuit and/or the prism may receive at least one laser light among the first laser light 20La, the second laser light 20Lb, and the third laser light 20Lc and may cause the at least one laser light to emit in a direction different from the upward direction. Alternatively, the planar lightwave circuit and/or the prism may receive at least two laser lights among the first laser light 20La, the second laser light 20Lb, and the third laser light 20Lc and may cause the at least two laser lights to emit in a direction different from the upward direction.

### Configuration Example of VCSEL Element 20

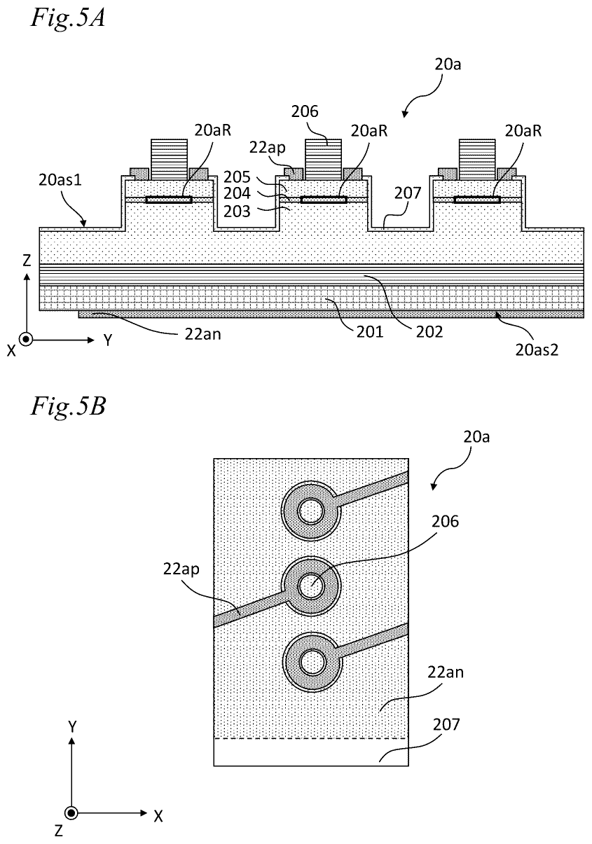

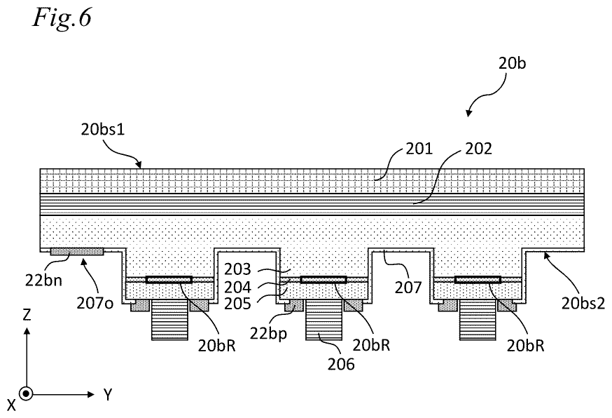

Subsequently, a configuration example of a part of the first VCSEL element 20a and the second VCSEL element 20b will be described with reference to FIGS. 5A to 6. The third VCSEL element 20c may have the same configuration as the second VCSEL element 20b and may be formed of a semiconductor material similar to that of the second VCSEL element 20b.

FIG. 5A is a cross-sectional view parallel to the YZ plane, schematically illustrating a part of the configuration example of the first VCSEL element 20a. FIG. 5B is a top view of a part of the configuration example illustrated in FIG. 5A. The first VCSEL element 20a illustrated in FIG. 5A has a layered structure in which a semiconductor substrate 201, an n-side reflective film 202, an n-type semiconductor layer 203, an active layer 204, a p-type semiconductor layer 205, and a p-side reflective film 206 are layered in this order. The conductivity types of the p-type and the n-type may be reversed. The semiconductor substrate 201 may be removed. The n-type semiconductor layer 203 includes a flat plate portion and a protruding portion protruding therefrom in the +Z direction. The active layer 204 is located on an upper surface of the protruding portion of the n-type semiconductor layer 203. The p-type semiconductor layer 205 is located on an upper surface of the active layer 204, and the p-side reflective film 206 is located in a region on the upper surface of the p-type semiconductor layer 205 other than a peripheral region thereof. In the above-described first VCSEL element 20a illustrated in FIG. 1, the active layer 204 is positioned closer to the lower surface 40s2 of the light-transmissive member 40 than to the upper surface 10s1 of the substrate 10. In this specification, the active layer 204 in the first VCSEL element 20a is also referred to as a “first active layer.”

The first VCSEL element 20a includes an insulating layer 207 that covers an upper surface of the flat plate portion and a lateral surface of the protruding portion of the n-type semiconductor layer 203, a lateral surface of the active layer 204, and a lateral surface and a peripheral region of an upper surface of the p-type semiconductor layer 205. The first VCSEL element 20a includes the first positive electrode 22ap electrically connected to the p-type semiconductor layer 205 and the first negative electrode 22an electrically connected to the semiconductor substrate 201. The uppermost surface of the first VCSEL element 20a is a surface of the p-side reflective film 206 on the side opposite to the surface in contact with the p-type semiconductor layer 205. The lower surface 20as2 of the first VCSEL element 20a is a lower surface of the semiconductor substrate 201.

In the example illustrated in FIG. 5B, the p-side reflective film 206, the insulating layer 207, and the first positive electrode 22ap are exposed in the top view: The first positive electrode 22ap includes a ring-shaped portion surrounding the p-side reflective film 206 and a linear portion extending from the ring-shaped portion in the top view: In order to prevent generation of a stepped portion due to the protruding portion of the insulating layer 207, an additional insulating layer, such as SiO₂, may be further provided on the insulating layer 207 and the first positive electrode 22ap may be provided over the additional insulating layer,

The n-side reflective film 202 and the p-side reflective film 206 may each be formed of, for example, a distributed Bragg reflector (DBR). The DBR has a structure in which a plurality of high refractive index layers and a plurality of low refractive index layers are alternately layered. The DBR includes a wavelength region of high reflectance called a stop band. A center wavelength and a wavelength width of the stop band are determined by a refractive index and a thickness of the high refractive index layer and a refractive index and a thickness of the low refractive index layer. The reflectance in the stop band of the DBR increases with difference between the refractive index of the high refractive index layer and the refractive index of the low refractive index layer and with the number of layers.

Examples of the first VCSEL element 20a that emits red first laser light may be formed of at least one selected from the group consisting of InAlGaP-based, GaInP-based, GaAs-based, and AlGaAs-based semiconductor materials. In the first VCSEL element 20a according to an aspect, the semiconductor substrate 201 is formed of n-type GaAs. The layered structure of the n-side reflective film 202 (p-side reflective film 206) is formed of n-type (p-type) AlGaAs having different composition ratios. The n-type semiconductor layer 203 (p-type semiconductor layer 205) is formed of n-type (p-type) AlGaInP. The active layer 204 is formed of GaInP.

In the example illustrated in FIG. 5A, a standing wave is formed between the n-side reflective film 202 and the p-side reflective film 206. A wavelength of the standing wave in the air is within stop bands of the n-side reflective film 202 and the p-side reflective film 206, and this wavelength is a first oscillation wavelength of the first laser light. An integral multiple of a half of the first oscillation wavelength is equal to an optical distance between reflective surfaces of the n-side reflective film 202 and the p-side reflective film 206 facing each other. The optical distance is a distance obtained by multiplying a distance in which light actually propagates through a certain medium by a refractive index of the medium. By applying a forward voltage between the first positive electrode 22ap and the first negative electrode 22an, current can be injected into the active layer 204. By the current injection, population inversion occurs in the active layer 204, and amplification of light by stimulated emission at the first oscillation wavelength, that is, laser oscillation occurs. A first light-emitting region 20aR in the first VCSEL element 20a is a region positioned inside the active layer 204 and is a region in which the intensity of the first laser light is 1/e² or more of the peak intensity thereof. e is the base of a natural logarithm. A region surrounded by a thick line illustrated in FIG. 5A represents the first light-emitting region 20aR. The first light-emitting region is positioned closer to the uppermost surface of the first VCSEL element 20a than to the lower surface 20as2 of the first VCSEL element 20a.

In the first VCSEL element 20a, a reflectance of the n-side reflective film 202 in the stop band is approximately 100%, and a reflectance of the p-side reflective film 206 in the stop band is slightly lower than the reflectance of the n-side reflective film 202, for example, 98%. Accordingly, the first laser light having the first oscillation wavelength in both stop bands passes through the p-side reflective film 206 and is emitted in the +Z direction.

FIG. 6 is a cross-sectional view parallel to the YZ plane, schematically illustrating a part of a configuration example of the second VCSEL element 20b. The second VCSEL element 20b illustrated in FIG. 6 is different from the first VCSEL element 20a illustrated in FIG. 5A in the following two configurations. The first difference is that the second VCSEL element 20b has a configuration in which the upper and lower sides are reversed compared with the first VCSEL element 20a. The semiconductor substrate 201 may be removed, or an anti-reflective film may be provided on the semiconductor substrate 201. The second difference is that the second negative electrode 22bn illustrated in FIG. 6 is electrically connected to the n-type semiconductor layer 203 via an opening 2070 provided in the insulating layer 207.

In the above-described second VCSEL element 20b illustrated in FIG. 1, the active layer 204 is positioned closer to the upper surface 10s1 of the substrate 10 than to the lower surface 40s2 of the light-transmissive member 40. In this specification, the active layer 204 in the second VCSEL element 20b is also referred to as a “second active layer.” The second positive electrode 22bp illustrated in FIG. 6 has the same configuration as the first positive electrode 22ap illustrated in FIG. 5A.

The upper surface 20bs1 of the second VCSEL element 20b is a surface of the semiconductor substrate 201 on the side opposite to the surface in contact with the n-side reflective film 202. The lowermost surface of the second VCSEL element 20b is a surface of the p-side reflective film 206 on the side opposite to the surface in contact with the p-type semiconductor layer 205. The same applies to the upper surface 20cs1 and the lower surface 20cs2 of the third VCSEL element 20c.

In one example, the second VCSEL element 20b that emits green second laser light may be formed of at least one semiconductor material selected from the group consisting of GaN, InGaN, and AlGaN. In the second VCSEL element 20b according to an aspect, the semiconductor substrate 201 is formed of GaN. The layered structure of the n-side reflective film 202 is formed of AlInN and GaN. The layered structure of the p-side reflective film 206 is formed of dielectric films of SiO₂, Nb₂O₅, and the like. The n-type semiconductor layer 203 (p-type semiconductor layer 205) is formed of n-type (p-type) GaN. The active layer 204 is formed of InGaN.

By applying the forward voltage between the second positive electrode 22bp and the second negative electrode 22bn illustrated in FIG. 6, the laser oscillation occurs, which is as described with reference to FIG. 5A. The second positive electrode 22bp and the second negative electrode 22bn illustrated in FIG. 6 are electrically connected to the second positive conductive member 12bp and the negative conductive member 12n illustrated in FIG. 1 described above, respectively. The gap between the second positive electrode 22bp and the second positive conductive member 12bp and the gap between the second negative electrode 22bn and the negative conductive member 12n may be filled with, for example, solder, or may be filled with a conductive member extending in the Z direction, such as a copper pillar, in addition to solder. With the conductive member, the possibility that the lowermost surface of the second VCSEL element 20b comes into contact with the upper surface 10s1 of the substrate 10 can be reduced.

In the second VCSEL element 20b, a reflectance of the p-side reflective film 206 in the stop band is approximately 100%, and a reflectance of the n-side reflective film 202 in the stop band is slightly lower than the reflectance of the p-side reflective film 206, for example, 98%. Accordingly, the second laser light having the second oscillation wavelength in both stop bands passes through the n-side reflective film 202 and the semiconductor substrate 201 in this order and is emitted in the +Z direction. A second light-emitting region 20bR in the second VCSEL element 20b is a region positioned inside the active layer 204 and is a region in which the intensity of the second laser light is 1/e² of the peak intensity thereof. A region surrounded by a thick line illustrated in FIG. 6 represents the second light-emitting region 20bR. The same applies to the third light-emitting region in the third VCSEL element 20c. The second light-emitting region is positioned closer to the lowermost surface than to the upper surface of the second VCSEL element 20b.

The second VCSEL element 20b that emits short-wavelength laser light is required to have higher heat dissipation than the first VCSEL element 20a that emits long-wavelength laser light. With the gap between the lower surface 20bs2 of the second VCSEL element 20b illustrated in FIG. 6 and the upper surface 10s1 of the substrate 10 illustrated in FIG. 1 described above filled with a material having high thermal conductivity, heat generated in the active layer 204 can be efficiently transmitted to the substrate 10. When heat dissipation is not considered, the second VCSEL element 20b may have a configuration similar to that of the first VCSEL element 20a. However, when the first VCSEL element 20a has the configuration similar to that of the second VCSEL element 20b, there is a possibility that laser light having a long wavelength is absorbed by the semiconductor substrate 201 and attenuated.

The configurations of the first VCSEL element 20a illustrated in FIG. 5A and the second VCSEL element 20b illustrated in FIG. 6 are examples. The components included in each VCSEL element 20 may be formed of known materials. The shapes of some of the components included in each VCSEL element 20 may be changed. Each VCSEL element 20) may further include other components. For example, the VCSEL element disclosed in JP 2020-123605 A may be used as the second VCSEL element 20b and/or the third VCSEL element 20c. The entire disclosure of JP 2020-123605 A is incorporated herein by reference.

Light-emitting devices according to the present disclosure include light-emitting devices according to following Aspects.

### Aspect 1

A light-emitting device comprising:
a substrate having an upper surface;
a light-transmissive member having a lower surface facing the upper surface of the substrate;
at least one surface emitting laser element disposed between the upper surface of the substrate and the lower surface of the light-transmissive member, the surface emitting laser element being configured to perform top emission; and
a resin disposed between the upper surface of the substrate and the lower surface of the light-transmissive member, the resin being in contact with the upper surface of the substrate and the lower surface of the light-transmissive member.

### Aspect 2

The light-emitting device according to Aspect 1, wherein a part of the resin is positioned between an upper surface of the at least one surface emitting laser element and the lower surface of the light-transmissive member.

### Aspect 3

The light-emitting device according to Aspect 1 or 2, wherein the light-transmissive member includes:
a light incident surface on which light emitted from each of the plurality of surface emitting laser elements is incident, the light incident surface located in a part of the lower surface, and
a light-emitting surface from which the light exits, the light-emitting surface positioned on a side opposite to the light incident surface, and
the light incident surface and the light-emitting surface are flat surfaces parallel to each other.

### Aspect 4

The light-emitting device according to any one of Aspects 1 to 3, further including an intermediate conductive component disposed between the upper surface of the substrate and the lower surface of the light-transmissive member, wherein
each of the substrate and the light-transmissive member includes a conductive member electrically connected to the intermediate conductive component, and
the at least one surface emitting laser element is electrically connected to the conductive member of the light-transmissive member.

### Aspect 5

The light-emitting device according to any one of Aspects 1 to 3, wherein
the substrate includes a conductive member, and
the at least one surface emitting laser element is electrically connected to the conductive member.

### INDUSTRIAL APPLICABILITY

The light-emitting device of the present disclosure can be used for devices, such as a head mounted display, a projector, a display, and lighting equipment.

### REFERENCE CHARACTERS LIST

10: Substrate, 10s1: Upper surface, 10s2: Lower surface, 10sa: First region, 10sb: Second region, 10sc: Third region, 10sd: Fourth region, 10se: Element region, 12ap: First positive conductive member, 12bp: Second positive conductive member, 12cp: Third positive conductive member, 12m, 22bm, 22cm, 42m1, 42m2: Metal film, 12n: Negative conductive member, 18: Bonding member, 20: VCSEL element, 20a: First VCSEL element, 20aR: First light-emitting region, 20as1: Upper surface of first VCSEL element, 20as2: Lower surface of first VCSEL element, 20b: Second VCSEL element, 20bR: Second light-emitting region, 20bs1: Upper surface of second VCSEL element, 20bs2: Lower surface of second VCSEL element, 20c: Third VCSEL element, 20cs1: Upper surface of third VCSEL element, 20cs2: Lower surface of third VCSEL element, 22an: First negative electrode, 22ap: First positive electrode, 22bn: Second negative electrode, 22bp: Second positive electrode, 22cn: Third negative electrode, 22cp: Third positive electrode, 30: Intermediate conductive component, 30s1: Upper surface of intermediate conductive component, 30s2: Lower surface of intermediate conductive component, 32: Intermediate conductive member, 40: Light-transmissive member, 40s1: Upper surface of light-transmissive member, 40s2: Lower surface of light-transmissive member, 42: Patterned conductive member, 50a: First dichroic mirror, 50b: Second dichroic mirror, 50c: Third dichroic mirror, 100A, 100B, 100C, 110A: Light-emitting device, 201: Semiconductor substrate, 202: n-side reflective film, 203: n-type semiconductor layer, 204: Active layer, 205: p-type semiconductor layer, 206: p-side reflective film, 207: Insulating layer, 2070: Opening

1. A light-emitting device comprising:
a substrate having an upper surface;
a light-transmissive member having a lower surface facing the upper surface of the substrate;
a plurality of surface emitting laser elements disposed between the upper surface of the substrate and the lower surface of the light-transmissive member, the surface emitting laser elements being configured to perform top emission; and
an intermediate conductive component disposed between the upper surface of the substrate and the lower surface of the light-transmissive member, wherein
the substrate comprises a first conductive member and a second conductive member,
the light-transmissive member comprises a third conductive member electrically connected to the first conductive member by the intermediate conductive component, and
the plurality of surface emitting laser elements comprise
a first laser element electrically connected to the third conductive member, and
a second laser element electrically connected to the second conductive member.

2. The light-emitting device according to claim 1, wherein
the first laser element comprises a first active layer closer to the lower surface of the light-transmissive member than to the upper surface of the substrate, and
the second laser element comprises a second active layer closer to the upper surface of the substrate than to the lower surface of the light-transmissive member.

3. The light-emitting device according to claim 1, wherein
the first laser element comprises one or more first electrodes used for emitting first light, the one or more first electrodes located on a side facing the lower surface of the light-transmissive member,
the one or more first electrodes are electrically connected to the third conductive member, and
the light-transmissive member is configured to transmit the first light.

4. The light-emitting device according to claim 3, wherein
the first laser element comprises a plurality of first light-emitting regions,
the one or more first electrodes are composed of a plurality of first electrodes used for emitting the first light from respective ones of the first light-emitting regions, and
the plurality of first electrodes are electrically connected to the third conductive member.

5. The light-emitting device according to claim 1, wherein
the second laser element comprises one or more second electrodes used for emitting second light, on a side facing the upper surface of the substrate, and the one or more second electrodes are electrically connected to the second conductive member, and
the light-transmissive member transmits the second light.

6. The light-emitting device according to claim 5, wherein
the second laser element comprises a plurality of second light-emitting regions,
the one or more second electrodes are composed of a plurality of second electrodes used for emitting the second light from the respective second light-emitting regions, and
the plurality of second electrodes are electrically connected to the second conductive member.

7. The light-emitting device according to claim 1, further comprising:
a resin disposed between the upper surface of the substrate and the lower surface of the light-transmissive member, the resin being in contact with the upper surface of the substrate and the lower surface of the light-transmissive member.

8. The light-emitting device according to claim 7, wherein
a part of the resin is positioned between an upper surface of each of the plurality of surface emitting laser elements and the lower surface of the light-transmissive member.

9. The light-emitting device according to claim 7, wherein
the light-transmissive member comprises:
a light incident surface on which light emitted from each of the plurality of surface emitting laser elements is incident, the light incident surface located in a part of the lower surface, and
a light-emitting surface from which the light exits, the light-emitting surface positioned on a side opposite to the light incident surface, and
the light incident surface and the light-emitting surface are flat surfaces parallel to each other.

10. The light-emitting device according to claim 1, wherein
the plurality of surface emitting laser elements are arranged in an element region on the upper surface of the substrate, and
the intermediate conductive component is disposed outside the element region on the upper surface of the substrate.

11. The light-emitting device according to claim 1, wherein
the substrate comprises a fourth conductive member,
the plurality of surface emitting laser elements comprise a third laser element electrically connected to the fourth conductive member,
the first laser element is configured to emit red light,
the second laser element is configured to emit green light, and
the third laser element is configured to emit blue light.

12. The light-emitting device according to claim 4, wherein
end portions of the plurality of first electrodes are positioned such that the plurality of first light-emitting regions are located between the end portions of the first electrodes,
the end portions of the plurality of first electrodes comprise at least one first end portion and at least one second end portion, the at least one first end portion positioned closer to the intermediate conductive component than the at least one second end portion, the at least one second end portion positioned farther from the intermediate conductive component than the at least one first end portion,
the third conductive member comprises:
at least one first patterned conductive member electrically connected to the at least one first end portion and
at least one second patterned conductive member electrically connected to the at least one second end portion, and
when seen along a direction perpendicular to the upper surface of the substrate, the at least one second patterned conductive member passes through an outer side of the at least one first patterned conductive member to bypass the plurality of first light-emitting regions.

13. The light-emitting device according to claim 4, wherein
the third conductive member comprises a plurality of patterned conductive members electrically connected to the respective first electrodes,
the first laser element comprises a third electrode on a side facing the upper surface of the substrate, and
each of the plurality of patterned conductive members comprises a portion overlapping with the third electrode when seen along a direction perpendicular to the upper surface of the substrate.

14. The light-emitting device according to claim 4, wherein
the third conductive member comprises a plurality of patterned conductive members electrically connected to the respective first electrodes, and
each of the plurality of patterned conductive members does not overlap with any portion of the second laser element when seen along a direction perpendicular to the upper surface of the substrate.

15. The light-emitting device according to claim 4, wherein
end portions of the plurality of first electrodes are positioned such that the plurality of first light-emitting regions are located between the end portions of the first electrodes, and comprise at least one first end portion and at least one second end portion, the at least one first end portion positioned closer to the intermediate conductive component than the at least one second end portion, the at least one second end portion positioned farther from the intermediate conductive component than the at least one first end portion,
the third conductive member comprises:
at least one first patterned conductive member electrically connected to the at least one first end portion, and
at least one second patterned conductive member electrically connected to the at least one second end portion,
the intermediate conductive component comprises:
at least one first intermediate conductive member electrically connected to the at least one first patterned conductive member, and
at least one second intermediate conductive member electrically connected to the at least one second patterned conductive member, and
the at least one second intermediate conductive member is positioned more away from the first laser element than the at least one first intermediate conductive member is.
